(19) United States
(12) Patent Application Publication
(10) Pub. No.: US 2025/0188590 A1
(43) Pub. Date: Jun. 12, 2025

(54) SPUTTERING TARGET, METHOD FOR PRODUCING SPUTTERING TARGET, OXIDE SEMICONDUCTOR THIN FILM, THIN FILM SEMICONDUCTOR DEVICE AND METHOD FOR PRODUCING SAME

(71) Applicant: ULVAC, INC., Chigasaki-shi, Kanagawa (JP)

(72) Inventors: Kenta TANINO, Chigasaki-shi (JP); Motoshi KOBAYASHI, Chigasaki-shi (JP); Taku HANNA, Chigasaki-shi (JP); Kouichi MATSUMOTO, Chigasaki-shi (JP)

(21) Appl. No.: 18/840,807

(22) PCT Filed: Feb. 16, 2023
(86) PCT No.: PCT/JP2023/005444

§ 371 Date: Aug. 22, 2024

(30) Foreign Application Priority Data
Feb. 25, 2022 (JP) 2022-028218

(51) Int. Cl. C23C 14/34; C23C 14/08; H10D 30/01; H10D 30/67

(52) U.S. Cl. CPC C23C 14/3414; C23C 14/08; H10D 30/031; H10D 30/67

(57) ABSTRACT

A sputtering target which is formed of an oxide sintered body of an oxide of indium, magnesium, and tin represented by formula In_{X}Mg_{Y}Sn_{Z}, wherein X is 0.32 to 0.65, Y is 0.17 to 0.46, Z is greater than 0 and 0.22 or smaller, satisfying X+Y+Z=1.

### CROSS-REFERENCE TO RELATED APPLICATIONS

The present Application for Patent is a National Stage Entry of International Application No. PCT/JP2023/005444, filed Feb. 16, 2023, which claims priority to Japanese Patent Application No. 2022-028218, filed Feb. 25, 2022. The disclosures of the priority documents are incorporated in their entirety by references therein.

### TECHNICAL FIELD

The present invention relates to a sputtering target, to a method for producing the sputtering target (hereinafter may also be referred to as a “sputtering target production method”), to an oxide semiconductor thin film, to a thin film semiconductor device, and to a method for producing the semiconductor device.

### BACKGROUND ART

In recent years, a thin film transistor (TFT) employing an In—Ga—Zn—O-type oxide (IGZO) semiconductor film serving as an active layer has been widely adapted to a variety of display devices, since higher electron mobility can be achieved as compared with a conventional TFT employing an amorphous silicon film as an active layer (see, for example, Patent Documents 1 to 3).

Specifically, Patent Document 1 discloses an organic EL display device which employs a TFT having an active layer for driving an organic EL element, the layer being formed of IGZO. Patent Document 2 discloses a thin film transistor which has a channel layer (active layer) formed of a-IGZO and which exhibits an electron mobility of 5 cm²/Vs or higher. Patent Document 3 discloses a thin film transistor which has an active layer formed of IGZO and which exhibits an on/off current ratio of 104 or greater.

### PRIOR ART DOCUMENTS

### Patent Documents

Patent Document 1: Japanese Patent Application Laid-Open (kokai) No. 2009-31750
Patent Document 2: Japanese Patent Application Laid-Open (kokai) No. 2011-216574
Patent Document 3: WO 2010/092810

### SUMMARY OF THE INVENTION

### Problems to be Solved by the Invention

In recent years, there is increasing demand for oxide semiconductors exhibiting higher electron mobility, in order to satisfy requirements for higher resolution, low power consumption, and higher frame rate of various display devices. However, in thin film transistors employing an active layer formed of IGZO, difficulty is encountered in achieving an electron mobility higher than 10 cm²/Vs. Thus, there is demand for a material used in a thin film transistor exhibiting higher electron mobility.

Separately, there has actually been developed a cap layer for suppressing etching damage to and influence of hydrogen in a CVD process on the active layer. However, the inhibitory effect is problematically unsatisfactory.

In addition, when such a cap layer is employed with respect to a high-electron mobility active layer, a rise in threshold voltage at an on/off timing is shifted, which is also problematic.

Under such circumstances, an object of the present invention is to provide a sputtering target which can provide an oxide semiconductor thin film suited for a cap layer with respect to a high-electron mobility active layer, and a production method therefor. Other objects are to provide an oxide semiconductor thin film and an oxide semiconductor thin film stacked body, a thin film semiconductor device, and a method for producing the semiconductor device.

### Means for Solving the Problems

The inventors have conducted extensive studies in order to attain the aforementioned objects, and have found that a thin film of an oxide containing indium, magnesium, and tin is suited for a cap layer for use in a high electron mobility environment. The present invention has been accomplished on the basis of this finding.

Accordingly, the present invention includes the following.

In a first mode of the present invention, there is provided a sputtering target which is formed of an oxide sintered body of an oxide of indium, magnesium, and tin represented by formula In_{X}Mg_{Y}Sn_{Z}, wherein X is 0.32 to 0.65, Y is 0.17 to 0.46, Z is greater than 0 and 0.22 or smaller, satisfying X+Y+Z=1.

A second mode of the present invention is directed to a specific embodiment of the sputtering target of the first mode, wherein the oxide sintered body further contains a group A element, which is defined as at least one element selected from among Si, Ti, W, Zr, Nb, Ni, Ge, Ta, Al, and Y.

A third mode of the present invention is directed to a specific embodiment of the sputtering target of the second mode, which contains Si in an amount of 4 at % or less, Ti in an amount of 6 at % or less, W in an amount of 6 at % or less, Zr in an amount of 7 at % or less, Nb in an amount of 7 at % or less, Ni in an amount of 7 at % or less, Ge in an amount of 7 at& or less, Ta in an amount of 8 at % or less, Al in an amount of 8 at % or less, and Y in an amount of 9 at % or less, and has a group A element content less than 10 at %.

A fourth mode of the present invention is directed to a specific embodiment of the sputtering target of any of the first to third modes, wherein the oxide sintered body further contains a group B element, which is defined as at least one element selected from among Mo, Sb, Hf, La, Fe, Ga, Zn, Ca, and Sr.

A fifth mode of the present invention is directed to a specific embodiment of the sputtering target of the fourth mode, which contains Mo in an amount of 10 at % or less, Sb in an amount of 13 at % or less, Hf in an amount of 13 at % or less, La in an amount of 13 at % or less, Fe in an amount of 21 at % or less, Ga in an amount of 27 at % or less, Zn in an amount of 38 at % or less, Ca in an amount of 38 at % or less, and Sr in an amount of 38 at % or less, wherein the total amount of the elements other than In, Mg, and Sn is 38 at % or less.

A sixth mode of the present invention is directed to a specific embodiment of the sputtering target of any of the first to fifth modes, which has a relative density of 90% or more.

In a seventh mode of the present invention, there is provided a method for producing a sputtering target, the method comprising mixing indium oxide powder, magnesium oxide powder, and tin oxide powder, and molding the mixture, to form a compact, and firing the compact at 1,100° C. to 1, 650° C., to thereby yield a sputtering target having an oxide sintered body.

In an eighth mode of the present invention, there is provided a method for producing a sputtering target having an oxide sintered body, the method comprising mixing an oxide, a hydroxide, or a carbonate salt of indium, magnesium, and tin; calcining the mixture at 1,000° C. to 1,500° C., to form a precursor powder; molding the precursor powder to form a compact; and firing the compact at 1,100° C. to 1, 650° C.

In a ninth mode of the present invention, there is provided an oxide semiconductor thin film which is formed of an oxide semiconductor containing an oxide of indium, magnesium, and tin represented by formula In_{X}Mg_{Y}Sn_{Z} as a main component, wherein X is 0.32 to 0.65, Y is 0.17 to 0.46, Z is greater than 0 and 0.22 or smaller, satisfying X+Y+Z=1.

A tenth mode of the present invention is directed to a specific embodiment of the oxide semiconductor thin film of the ninth mode, wherein the etching rate in etching with a sulfuric acid-nitric acid-based etchant or an acetic acid-based etchant is 1 nm/sec or more.

An eleventh mode of the present invention is directed to a specific embodiment of the oxide semiconductor thin film of the ninth or tenth mode, which exhibits a band gap of 2.5 eV to 3.4 eV, and a resistivity of 1E+2Ω/square or higher after hydrogen annealing.

A twelfth mode of the present invention is directed to a specific embodiment of the oxide semiconductor thin film of the ninth to eleventh modes, which further contains a group A element, which is defined as at least one element selected from among Si, Ti, W, Zr, Nb, Ni, Ge, Ta, Al, Y, and Mo.

A thirteenth mode of the present invention is directed to a specific embodiment of the oxide semiconductor thin film of the twelfth mode, which contains Si in an amount of 4 at % or less, Ti in an amount of 6 at % or less, W in an amount of 6 at % or less, Zr in an amount of 7 at % or less, Nb in an amount of 7 at % or less, Ni in an amount of 7 at % or less, Ge in an amount of 7 at % or less, Ta in an amount of 8 at % or less, Al in an amount of 8 at % or less, and Y in an amount of 9 at % or less, and has a group A element content less than 10 at %.

More preferably, the oxide semiconductor film has high electrical resistance, and the Eg is not so high (Eg≤3.4).

A fourteenth mode of the present invention is directed to a specific embodiment of the oxide semiconductor thin film of the ninth to thirteenth modes, which further contains a group B element, which is defined as at least one element selected from among Mo, Sb, Hf, La, Fe, Ga, Zn, Ca, and Sr.

A fifteenth mode of the present invention is directed to a specific embodiment of the oxide semiconductor thin film of the fourteenth mode, which contains Mo in an amount of 10 at& or less, Sb in an amount of 13 at % or less, Hf in an amount of 13 at % or less, La in an amount of 13 at % or less, Fe in an amount of 21 at % or less, Ga in an amount of 27 at % or less, Zn in an amount of 38 at % or less, Ca in an amount of 38 at % or less, and Sr in an amount of 38 at % or less, wherein the total amount of the elements other than In, Mg, and Sn is 38 at % or less.

More preferably, the oxide semiconductor film has high electrical resistance, and the Eg is not so high (Eg≤3.4).

In a sixteenth mode of the present invention, there is provided an oxide semiconductor thin film stacked body which comprises an active layer formed of an oxide semiconductor thin film exhibiting a high electron mobility; and a cap layer which is stacked on the active layer and is formed of an oxide semiconductor thin film as recited in the ninth to fifteenth modes.

A seventeenth mode of the present invention is directed to a specific embodiment of the oxide semiconductor thin film stacked body of the sixteenth mode, wherein the cap layer has an etching rate suited for patterning with the active layer.

An eighteenth mode of the present invention provides a thin film semiconductor device having a cap layer formed of an oxide semiconductor thin film as recited in the ninth to fifteenth modes.

A nineteenth mode of the present invention is directed to a specific embodiment of the thin film semiconductor device of the eighteenth mode, wherein the cap layer is disposed so as to cover the active layer formed of an oxide semiconductor thin film exhibiting a high electron mobility.

A twentieth mode of the present invention is directed to a specific embodiment of the thin film semiconductor device of the eighteenth or nineteenth mode, which comprises a gate electrode; a gate insulating film disposed on the gate electrode; an active layer formed of an oxide semiconductor thin film exhibiting a high electron mobility and disposed on the gate insulating film; a cap layer disposed so as to cover the active layer; and a source electrode and a drain electrode connected to the active layer and the cap layer.

In a twenty-first mode of the present invention, there is provided a method for producing a thin film semiconductor device having a cap layer formed of an oxide semiconductor thin film as recited in the ninth to fifteenth modes, the method comprising forming a gate insulating film on a gate electrode; forming an active layer formed of an oxide semiconductor thin film exhibiting a high electron mobility on the gate insulating film through sputtering; forming the cap layer on the active layer through sputtering; patterning a stacked film of the active layer and the cap layer; forming a metal layer disposed on the active layer and the cap layer which have been patterned and serve as an underlayer film; and patterning the metal layer through wet etching, to thereby form a source electrode and a drain electrode.

### Effects of the Invention

According to the present invention, the oxide thin film containing indium, magnesium, and tin is most suitable for a cap layer for use in a high electron mobility environment. The cap layer can suppress etching damage and influence of hydrogen in a CVD process. By use of the cap layer, a thin film transistor exhibiting an electron mobility higher than 10 cm²/Vs can be fabricated.

The cap layer of the present invention can be formed of a zinc-free oxide semiconductor thin film, whereby etching by use of a sulfuric acid-nitric acid-based etchant or an acetic acid-based etchant can be achieved. Thus, patterning with an active layer exhibiting high electron mobility can be suitably performed. As a result, a super-fine thin film transistor can be fabricated through high-precision patterning.

### BRIEF DESCRIPTION OF THE DRAWINGS

FIG. 1 is a chart showing an etching rate (within 1 nm/sec) profile of thin film of a ternary complex oxide of In, Mg, and Sn.

FIG. 2 is a chart showing a band gap (3.4 eV or lower) profile of thin film of ternary complex oxide of In, Mg, and Sn.

FIG. 3 is a chart showing a resistivity range of 1E+2Ω/square or higher of thin film of a ternary complex oxide of In, Mg, and Sn, after hydrogen annealing.

FIG. 4 is a chart showing an integrated range of FIGS. 1 to 3.

FIG. 5 is a chart showing ranges ensuring Y≤X/2+2Z (wherein X, Y, and Z is those of In_{X}Mg_{Y}Sn_{Z}) in a ternary complex oxide of In, Mg, and Sn.

FIG. 6 is a schematic view of a configuration of the thin film transistor of the present invention.

FIG. 7 is a series of exemplary schematic views of a method of producing the thin film transistor of the present invention.

FIG. 8 is a series of exemplary schematic views of a method of producing the thin film transistor of the present invention.

FIG. 9 is a graph showing an S value profile in thin film transistors, in comparison of a case having a cap layer 14 formed of an oxide semiconductor thin film (i.e., a stacked layer) with a case a layer without provision of the cap layer 14 (i.e., a single layer), under modification of the substrate temperature in CVD to form a protective layer 16.

FIG. 10 is a graph showing comparison of Vth of thin film transistor between Production Example 1 and Comparative Production Example 1.

FIG. 11 is a graph showing comparison of Vth of thin film transistor between Comparative Production Example 1 and Comparative Production Example 2.

### MODES FOR CARRYING OUT THE INVENTION

In reference to the drawings, embodiments of the present invention will be described.

Before mentioning the sputtering target according to the present embodiment (i.e., an oxide semiconductor sputtering target), characteristics of the oxide semiconductor thin film formed from the sputtering target will be described in detail.

### [Oxide Semiconductor Thin Film]

An oxide semiconductor thin film is employed as, for example, a cap layer with respect to a high-electron mobility active layer (i.e., an inversion layer) of a so-called bottom gate-type thin film transistor (e.g., a field effect transistor).

The term “high-electron mobility active layer” refers to an active layer exhibiting a band gap of 3 eV or less. The electron mobility is 15 cm²/V·s or higher.

Typical examples of the material of the high-electron mobility oxide semiconductor include ITO (In—Sn—O)-type material and IGZO (In—Ga—Zn—O)-type material. These oxide semiconductor materials assume amorphous in crystallinity immediately after film formation and facilitate patterning through wet etching.

Also, there are proposed such high-electron mobility active layers as shown in Table 1 below. Table 1 shows properties including band gap, carrier concentration, and electron mobility. In any case, the band gap is 3 eV or less, and the electron mobility is higher than 15 cm²/V·s.

TABLE 1

| | | Carrier density | Hall mobility |
|---|---|---|---|
| | E.g. (eV) | (/cm³) | (cm²/V · s) |
| In—Zn—O | 2.5 | ~1E+20 | ~40 |
| In—W—O | 2.6 | ~1E+11 | ~40 (TFT mobility) |
| In—W—Zn—O | 2.7 | ~1E+19 | ~40 (TFT mobility) |
| In—Ga—Zn—Sn—O | 2.8 | ~9.9E+16 | ~18.5 |
| In—Zn—Ti—O | 2.7 | ~6.7E+17 | ~18.7 |
| In—Sn—Ge—O + α | 2.6~2.7 | ~4.4E+18 | ~27.2 |

As shown in Table 1, the high-electron mobility active layers tend to have a small band gap Eg and a high carrier concentration. The oxide semiconductor thin film of the present invention is most suited for serving as a cap layer with respect to such a high-electron mobility active layer.

Generally, the cap layer is disposed in order to suppress damage of the active layer during etching. In addition to suppression of damage of the active layer during etching, the oxide semiconductor thin film of the present invention can suppress influence of hydrogen during a CVD process.

The oxide semiconductor thin film of the present invention is formed of indium, magnesium, and tin, and the composition thereof is represented by formula In_{X}Mg_{Y}Sn_{Z}. In the formula, X is 0.32 to 0.65; Y is 0.17 to 0.46; Z is greater than 0 and 0.22 or smaller, with X+Y+Z=1 being satisfied.

Conventionally known cap layers generally have a composition rich in zinc. However, the present invention has realized a cap layer formed of an oxide semiconductor thin film having a zinc-free composition.

The cap layer having such a composition can be etched with a sulfuric acid-nitric acid-based etchant or an acetic acid-based etchant. The etching rate in etching with a sulfuric acid-nitric acid-based etchant or an acetic acid-based etchant is 1 nm/sec or higher.

Since such an etching rate is also equivalent to that of the high-electron mobility active layer, the condition is suited for etching the cap layer together with the active layer. Thus, a stacked body of the active layer and the cap layer can be favorably patterned at high precision.

In addition, etching damage of the active layer, and influence of hydrogen during a CVD process can also be successfully suppressed.

Meanwhile, the sulfuric acid-nitric acid-based etchant is an etchant mainly containing sulfuric acid and nitric acid. An example of the etchant contains H₂SO₄ (7.6 to 8.4%)+HNO₃ (3.8 to 4.2%). The acetic acid-based etchant is an etchant mainly containing acetic acid (CH₃COOH).

Other than the sulfuric acid-nitric acid-based etchant or the acetic acid-based etchant, an example of generally employed etchants is PAN, which is a liquid mixture containing phosphoric acid (H₃PO₄: <80%, nitric acid (HNO₃<5%), and acetic acid (CH₃COOH<10%). When PAN is used, the etchant preferably contains Zn. As describe below, the oxide semiconductor thin film of the present invention may also contain Zn. Thus, the oxide semiconductor thin film of the present invention may also be subjected to etching by use of PAN.

Needless to say, the etching rate can be tuned so as to be suited for the active layer etching rate. As a result, etching damage of the active layer, and influence of hydrogen during a CVD process can also be successfully suppressed.

By use of the cap layer of the present invention as described above, a thin film transistor exhibiting an electron mobility higher than 10 cm²/Vs can be provided.

When the oxide semiconductor thin film of the present invention is stacked as a cap layer on a high-electron mobility active layer to thereby yield a thin film transistor, shifting of a threshold voltage Vth can be suppressed, as compared with the case in which no cap layer is used. As a result, a thin film transistor exhibiting favorable TFT characteristics can be provided. Notably, the term “threshold voltage Vth” refers to a voltage at which a current-off state changed to a current-on state.

The composition of the oxide semiconductor thin film of the present invention is represented by formula In_{X}Mg_{Y}Sn_{Z}, wherein X is 0.32 to 0.65; Y is 0.17 to 0.46; Z is greater than 0 and 0.22 or smaller, with X+Y+Z=1 being satisfied. The compositional ranges are determined through the following procedure.

In the present invention, In is used as a carrier-generator, and Mg is used as a carrier-killer. Mg can serve as a hydrogen-getter that can control etching and remove hydrogen in CVD. Sn can control etching and electron mobility.

The compositional range of each element is determined in consideration of achieving an etching rate of 1 nm/sec or higher in etching with a sulfuric acid-nitric acid-based etchant or an acetic acid-based etchant, a band gap of 3.4 eV or less, a resistivity after hydrogen annealing of 1E+2Ω/square or higher, and other factors.

That is, the compositional ranges in the aforementioned formula is as follows: X is 0.32 to 0.65; Y is 0.17 to 0.46; Z is greater than 0 and 0.22 or smaller, with X+Y+Z=1 being satisfied.

Firstly, in an In—Mg—Sn ternary composite oxide thin film, compositional ranges so as to achieve an etching rate of 1 nm/sec are determined. As an etchant, an acetic acid-based etchant (acetic acid (CH₃COOH)) or a mixed acid etchant of sulfuric acid (7.6 to 8.4%) and nitric acid (3.8 to 4.2%) is used. The etching rate is determined through a Dip method, in which a single cap layer of an oxide semiconductor thin film is immersed in an etchant controlled at 40° C. immediately after film formation.

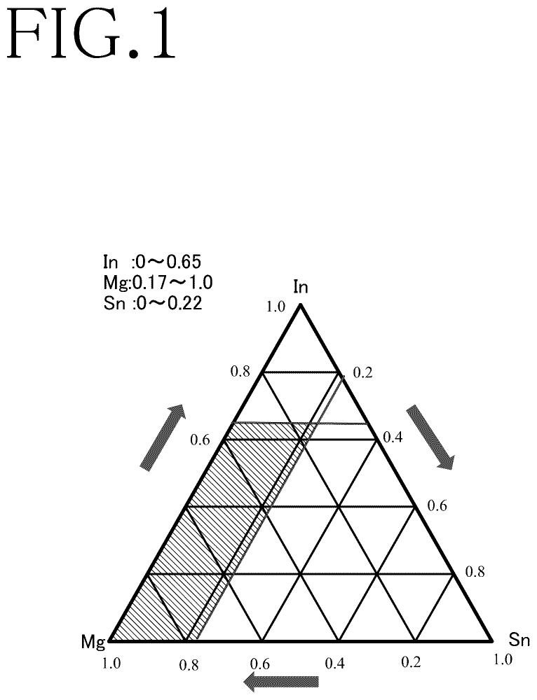

FIG. 1 shows the results. An etching rate of 1 nm/sec or more is achieved, when the conditions: 0<In≤0.65, 0.17≤Mg<1.0, and 0<Sn≤0.22 are satisfied.

Next, the band gap of an In—Mg—Sn ternary composite oxide thin film is determined through the following procedure.

1. Transmittance T and reflectance R are measured by means of a spectrometer.

2. Absorption coefficient α is calculated by the following equation:

$$α = ( ( ( - ln ( T / ( 1 - R ) ) / n ) / ( T / ( 1 - R ) )$$

(wherein n represents a thickness [cm], and T and R are measurement/100).

3. (α×hω)\hat{ }(½) is calculated.

(In the equation, ho represents energy of a photon [eV]: 1239.8/wavelength [nm].)

4. In a graph showing the relationship between hω [eV] (horizontal axis) and (α×hω)\hat{ }(½) (vertical axis), the value of an intersection point between a tangential line having a maximum slope and the x-axis is employed as a band gap.

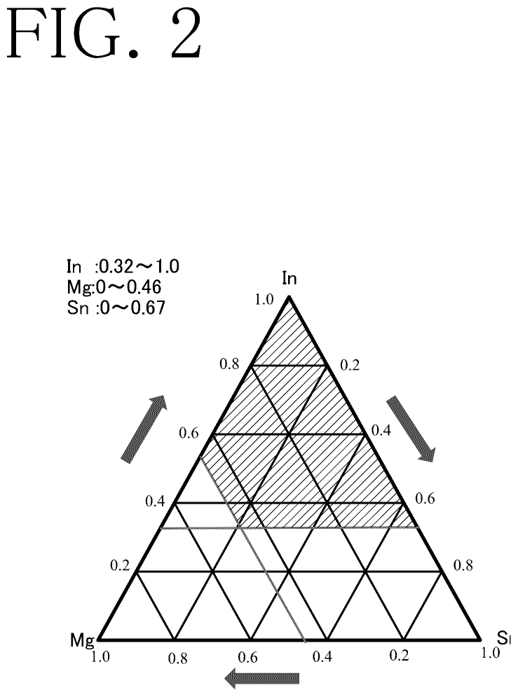

FIG. 2 shows the results. A band gap of 3.4 eV or lower is achieved, when the conditions: 0.32≤In<1.0, 0<Mg≤0.46, and 0<Sn≤0.67 are satisfied.

The reason why a band gap of 3.4 eV or lower is preferred is as follows. In order to gain favorable TFT characteristics, the difference in Eg between the upper layer and the lower layer is important. When Eg is greater than 3.4 eV (i.e., the difference between the cap layer and the active layer is excessively large), electrons in the upper layer flow into the lower layer (i.e., an active layer) during joining of semiconductors. As a result, the Fermi level of the active layer may be undesirably shifted to a level almost equivalent to that of the conduction band. In the above case, probability of excitation of electrons to the conduction band increases, and the threshold voltage of TFT is shifted toward the minus direction, problematically failing to achieve favorable TFT characteristics.

After hydrogen annealing, the resistivity of the In—Mg—Sn ternary composite oxide thin film is further determined. Hydrogen annealing is performed at 400° C. for 1 hour with a gas mixture of Ar+H₂ (H₂: 6 at %) at a flow rate of 1 L/min.

The resistivity is measured on the basis of the Hall effect.

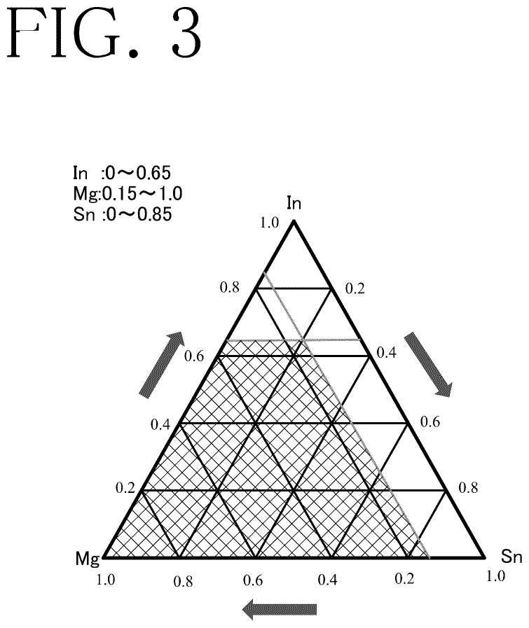

FIG. 3 shows the results. A resistivity of 1E+2 or higher is achieved, when the conditions: 0<In≤0.65, 0.15≤Mg<1.0, 0<Sn≤0.85 are satisfied.

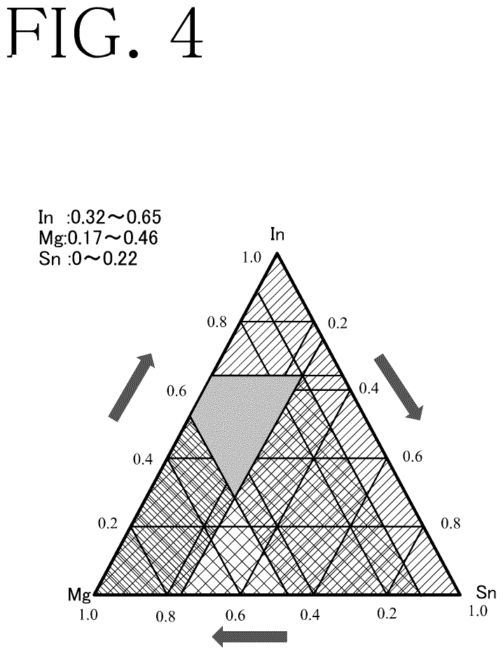

FIG. 4 shows the integrated feature of the results in terms of the compositional ranges of FIGS. 1 to 3. As is clear from FIG. 4, all of the aforementioned elements are achieved, when the conditions: 0.32≤In≤0.65, 0.17≤Mg≤0.46, 0<Sn>0.22 are satisfied.

The oxide semiconductor thin film of the present invention may further contain a group A element, which is defined as at least one element selected from among Si, Ti, W, Zr, Nb, Ni, Ge, Ta, Al, and Y.

Preferably, the group A elements include Si in an amount of 4 at % or less, Ti in an amount of 6 at % or less, W in an amount of 6 at % or less, Zr in an amount of 7 at % or less, Nb in an amount of 7 at % or less, Ni in an amount of 7 at % or less, Ge in an amount of 7 at % or less, Ta in an amount of 8 at % or less, Al in an amount of 8 at % or less, and Y in an amount of 9 at % or less. Preferably, the entire group A element content is less than 10 at %. Preferably, the oxide semiconductor film has high electrical resistance, and the Eg is not so high (Eg≤3.4).

Also preferably, the oxide semiconductor thin film of the present invention may further contain a group B element, which is defined as at least one element selected from among Mo, Sb, Hf, La, Fe, Ga, Zn, Ca, and Sr.

Preferably, the group B elements include Mo in an amount of 10 at % or less, Sb in an amount of 13 at % or less, Hf in an amount of 13 at % or less, La in an amount of 13 at % or less, Fe in an amount of 21 at % or less, Ga in an amount of 27 at % or less, Zn in an amount of 38 at % or less, Ca in an amount of 38 at % or less, and Sr in an amount of 38 at % or less, wherein the total amount of the elements other than In, Mg, and Sn is 38 at % or less. Preferably, the oxide semiconductor film has high electrical resistance, and the Eg is not so high (Eg≤3.4).

Preferred compositional ranges of the group A elements and the group B elements are determined through the following procedure.

The band gap Eg (eV) are determined, when any of the group A elements and the group B elements is added to the essential three elements In, Mg, and Sn. Table 2 shows the results.

Table 2 shows the results of maintenance of a band gap Eg (eV) of 3.4 eV or less. The symbol “O” denotes the case of 3.4 eV or lower, and the symbol “X” higher than 3.4 eV.

The limiting value of the band gap Eg of the cap layer; i.e., 3.4 eV, has been set on the basis of a band gap range in which shifting of TFT does not occur. In other words, the amount of additional element α added to InMgSn (Eg: 3.1 eV) which ensures maintenance of an Eg of 3.4 eV or less is shown.

Group A elements; Si, Ti, W, Zr, Nb, Ni, Ge, Ta, Al, and Y can maintain an Eg of 3.4 eV or less, when added in an amount less than 10 at %.

Group B elements; Mo, Sb, Hf, La, Fe, Ga, Zn, Ca, and Sr can maintain an Eg of 3.4 eV or less, when added in an amount in excess of 10 at %.

TABLE 2

| | | Additional amount [at %] | | | | | | | | | | | | | | | | | | |
|---|---|---|---|---|---|---|---|---|---|---|---|---|---|---|---|---|---|---|---|---|
| Group | α | 1 | 2 | 3 | 4 | 5 | 6 | 7 | 8 | 9 | 10 | 11 | 12 | 13 | ~ | 21 | ~ | 27 | ~ | 38 |
| A | Si | ◯ | ◯ | ◯ | ◯ | X | X | X | X | X | X | X | X | X | X | X | X | X | X | X |
| | Ti | ◯ | ◯ | ◯ | ◯ | ◯ | ◯ | X | X | X | X | X | X | X | X | X | X | X | X | X |
| | W | ◯ | ◯ | ◯ | ◯ | ◯ | ◯ | X | X | X | X | X | X | X | X | X | X | X | X | X |
| | Zr | ◯ | ◯ | ◯ | ◯ | ◯ | ◯ | ◯ | X | X | X | X | X | X | X | X | X | X | X | X |
| | Nb | ◯ | ◯ | ◯ | ◯ | ◯ | ◯ | ◯ | X | X | X | X | X | X | X | X | X | X | X | X |
| | Ni | ◯ | ◯ | ◯ | ◯ | ◯ | ◯ | ◯ | X | X | X | X | X | X | X | X | X | X | X | X |
| | Ge | ◯ | ◯ | ◯ | ◯ | ◯ | ◯ | ◯ | X | X | X | X | X | X | X | X | X | X | X | X |
| | Ta | ◯ | ◯ | ◯ | ◯ | ◯ | ◯ | ◯ | ◯ | X | X | X | X | X | X | X | X | X | X | X |
| | Al | ◯ | ◯ | ◯ | ◯ | ◯ | ◯ | ◯ | ◯ | X | X | X | X | X | X | X | X | X | X | X |
| | Y | ◯ | ◯ | ◯ | ◯ | ◯ | ◯ | ◯ | ◯ | ◯ | X | X | X | X | X | X | X | X | X | X |
| B | Mo | ◯ | ◯ | ◯ | ◯ | ◯ | ◯ | ◯ | ◯ | ◯ | ◯ | X | X | X | X | X | X | X | X | X |
| | Sb | ◯ | ◯ | ◯ | ◯ | ◯ | ◯ | ◯ | ◯ | ◯ | ◯ | ◯ | ◯ | ◯ | X | X | X | X | X | X |
| | Hf | ◯ | ◯ | ◯ | ◯ | ◯ | ◯ | ◯ | ◯ | ◯ | ◯ | ◯ | ◯ | ◯ | X | X | X | X | X | X |
| | La | ◯ | ◯ | ◯ | ◯ | ◯ | ◯ | ◯ | ◯ | ◯ | ◯ | ◯ | ◯ | ◯ | X | X | X | X | X | X |
| | Fe | ◯ | ◯ | ◯ | ◯ | ◯ | ◯ | ◯ | ◯ | ◯ | ◯ | ◯ | ◯ | ◯ | ◯ | ◯ | X | X | X | X |
| | Ga | ◯ | ◯ | ◯ | ◯ | ◯ | ◯ | ◯ | ◯ | ◯ | ◯ | ◯ | ◯ | ◯ | ◯ | ◯ | ◯ | ◯ | X | X |
| | Zn | ◯ | ◯ | ◯ | ◯ | ◯ | ◯ | ◯ | ◯ | ◯ | ◯ | ◯ | ◯ | ◯ | ◯ | ◯ | ◯ | ◯ | ◯ | ◯ |
| | Ca | ◯ | ◯ | ◯ | ◯ | ◯ | ◯ | ◯ | ◯ | ◯ | ◯ | ◯ | ◯ | ◯ | ◯ | ◯ | ◯ | ◯ | ◯ | ◯ |
| | Sr | ◯ | ◯ | ◯ | ◯ | ◯ | ◯ | ◯ | ◯ | ◯ | ◯ | ◯ | ◯ | ◯ | ◯ | ◯ | ◯ | ◯ | ◯ | ◯ |

### [Sputtering Target]

Next will be described an embodiment of the sputtering target of the invention.

The sputtering target may be a planar-shape target or a cylindrical rotary target. The sputtering target is formed of a sintered body of an oxide semiconductor containing In, Mg, and Sn, and the compositional proportions and preferred compositional proportions thereof are the same as those of the aforementioned oxide semiconductor thin film. Thus, overlapping descriptions will be omitted.

In the sputtering target of the present invention, the sintered body of the oxide semiconductor is represented by formula In_{X}Mg_{Y}Sn_{Z}, wherein X is 0.32 to 0.65, Y is 0.17 to 0.46, Z is greater than 0 and 0.22 or smaller, satisfying X+Y+Z=1.

In addition to In, Mg, Sn, the oxide semiconductor sintered body of the sputtering target of the present invention may further contain a group A element, which is defined as at least one element selected from among Si, Ti, W, Zr, Nb, Ni, Ge, Ta, Al, and Y.

Preferably, the group A elements include Si in an amount of 4 at % or less, Ti in an amount of 6 at % or less, W in an amount of 6 at % or less, Zr in an amount of 7 at % or less, Nb in an amount of 7 at % or less, Ni in an amount of 7 at& or less, Ge in an amount of 7 at % or less, Ta in an amount of 8 at % or less, Al in an amount of 8 at % or less, and Y in an amount of 9 at % or less, and the entire group A element content is less than 10 at %.

The oxide semiconductor sintered body of the sputtering target of the present invention may further contain a group B element, which is defined as at least one element selected from among Mo, Sb, Hf, La, Fe, Ga, Zn, Ca, and Sr.

Preferably, the group B elements include Mo in an amount of 10 at % or less, Sb in an amount of 13 at % or less, Hf in an amount of 13 at % or less, La in an amount of 13 at % or less, Fe in an amount of 21 at % or less, Ga in an amount of 27 at % or less, Zn in an amount of 38 at % or less, Ca in an amount of 38 at % or less, and Sr in an amount of 38 at % or less, wherein the total amount of the elements other than In, Mg, and Sn is 38 at % or less.

The oxide semiconductor thin film formed by use of the sputtering target has the following characteristics: the etching rate in etching with a sulfuric acid-nitric acid-based etchant or an acetic acid-based etchant is 1 nm/sec or more; the band gap is 2.5 eV to 3.4 eV; and the resistivity after hydrogen annealing is 1E+2Ω/square or higher. Thus, the oxide semiconductor thin film is most suited for use with s high-electron mobility cap layer. Notably, the term “high-electron mobility active layer” refers to the same as described above; i.e., an active layer exhibiting a band gap of 3 eV or less. The electron mobility is 15 cm²/V·s or higher.

Generally, the cap layer is disposed in order to suppress damage of the active layer during etching. In addition to suppression of capping damage of the active layer, the oxide semiconductor thin film formed from the sputtering target of the present invention can suppress influence of hydrogen during a CVD process.

The cap layer having such a composition can be etched with a sulfuric acid-nitric acid-based etchant or an acetic acid-based etchant. The etching rate in etching with a sulfuric acid-nitric acid-based etchant or an acetic acid-based etchant is 1 nm/sec or higher.

Since such an etching rate is also equivalent to that of the high-electron mobility active layer, the condition is suited for etching the cap layer together with the active layer. Thus, a stacked body of the active layer and the cap layer can be favorably patterned at high precision.

In addition, etching damage of the active layer, and influence of hydrogen during a CVD process can also be successfully suppressed.

When PAN is used as an etchant, the sputtering target preferably contains Zn. The oxide semiconductor thin film formed from the sputtering target can also be subjected to etching by use of PAN.

Needless to say, in this case, the etching rate can be tuned so as to be suited for the active layer etching rate. As a result, etching damage of the active layer, and influence of hydrogen during a CVD process can also be successfully suppressed.

By use of the cap layer formed of the oxide semiconductor thin film produced from the sputtering target of the present invention, a thin film transistor exhibiting an electron mobility higher than 10 cm²/Vs can be provided. Also, when the aforementioned oxide semiconductor thin film is stacked as a cap layer on a high-electron mobility active layer to thereby yield a thin film transistor, shifting of a threshold voltage Vth can be suppressed, as compared with the case in which no cap layer is used. As a result, a thin film transistor exhibiting favorable TFT characteristics can be provided.

### (Sputtering Target Production Method)

No particular limitation is imposed on the sputtering target of the present invention, so long as a sintered body of the oxide semiconductor having the aforementioned composition can be produced. Examples of the production method include the following two procedures.

In a first production method, an indium oxide powder, a magnesium oxide powder, and a tin oxide powder are mixed together, and the mixture is molded into a compact. The compact is fired at 1,100° C. to 1, 650° C., to thereby yield a sputtering target formed of an oxide sintered body.

The proportions by weight of the raw material powders are predetermined so as to achieve the target element proportions of the aforementioned oxide semiconductor sintered body.

In the sputtering target production method of the present invention, MgO serving as a raw material reacts with water to form Mg(OH)₂ during mixing of raw materials. In this case, the viscosity of the slurry increases during mixing of raw materials, and uniform mixing may possibly be impeded. In addition, Mg(OH)₂ may possibly provide pores and cracks during sintering.

Thus, when the raw materials contain magnesium oxide, preferably, the raw materials are mixed under dry conditions, or mixed to form a slurry of a water-free organic solvent. Needless to say, mixing in pure water can be possibly accomplished, if particular care such as shortening the mixing time is taken.

In a second production method, an oxide, a hydroxide, or a carbonate salt of indium, magnesium, and tin are mixed together, and the mixture is calcined at 1,000° C. to 1, 500° C., to thereby form a powder of a precursor. The precursor powder is molded into a compact, and the compact is fired at 1,100° C. to 1,650° C., to thereby yield a sputtering target formed of an oxide sintered body.

The proportions by weight of the raw material powders are predetermined so as to achieve the target element proportions of the aforementioned oxide semiconductor sintered body.

The oxide sintered body included in the sputtering target is subjected to the following procedures.

Specifically, an oxide, a hydroxide, or a carbonate salt of indium, magnesium, and tin are mixed together, and the mixture is calcined at 1,000° C. to 1,500° C., to thereby form a powder of a precursor. The precursor powder is molded into a compact, and the compact is fired at 1, 100° C. to 1, 650° C., to thereby yield a sputtering target formed of an oxide sintered body.

In the sputtering target production method of the present invention, the raw material powder mixture is calcined at 1,000° C. to 1,500° C., to thereby prepare a powder free-from an MgO phase. The thus-treated powder mixture is mixed and granulated under dry conditions, and then a compact is yielded. Therefore, formation of Mg(OH)₂, which would otherwise be formed through reaction of the powder with water during mixing after calcination, is prevented. As a result, possible inhibition of uniform mixing due to a rise in slurry viscosity, and that of provision of pores and cracks during sintering of the hydroxide can be avoided.

Meanwhile, the compact is fired at 1,100° C. to 1, 650° C., to thereby yield a corresponding sintered body.

When the firing temperature is lower than 1, 100° C., the conductivity and relative density of the product are low, which makes the product to be fitted as a target. When the firing temperature is higher than 1, 650° C., a part of the components evaporates. In this case, the composition of the fired body may vary, and coarse crystal grains may be provided to reduce the mechanical strength of the fired body.

In the sputtering target of the present invention, compositional ranges which are preferred to prevent formation of Mg(OH)₂ exist.

In the definition In:Mg:Sn=a (at %):b(at %):c(at %), MgO remains after calcination and sintering in a range satisfying b>a/2+2c, which is not preferred. When MgO remains after sintering, it may react on the surface of a sputtering target with water contained in air, to form Mg(OH)₂, which may be a possible source of particles.

The above range condition corresponds to Y>X/2+2Z, when the parameters a, b, and c are converted to X, Y, and Z in In_{X}Mg_{Y}Sn_{Z}.

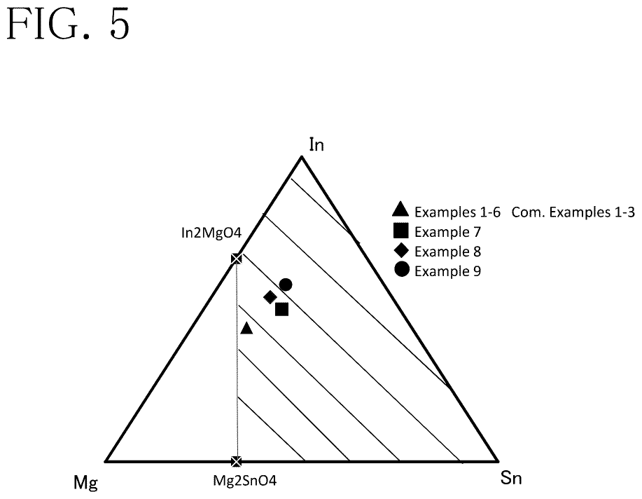

FIG. 5 shows the converted range conditions.

As shown in FIG. 5, an area corresponding to Y≤x/2+2Z is represented by a hatched area. In the specified area, a crystalline phase formed of an In₂MgO₄ phase, an Mg₂SnO₄ phase, an In₂O₃ phase, an SnO₂ phase, and the like, but including no MgO phase is present. Notably, FIG. 5 shows data in relation to the below-mentioned Examples 1 to 9 and Comparative Examples 1 to 3.

The sputtering target of the present invention preferably has a relative density of 90% or higher. When the relative density is lower than 90%, cracking and generation of particles may possibly occur during sputtering. Therefore, the sputtering target is preferably produced so that the relative density is controlled to 90% or higher.

Hereinafter, the production method of the invention will be further described in detail, in reference to an embodiment of the second production method.

In the embodiment, raw material powders are granulated through spray drying, which allows drying and granulation to be conducted simultaneously. Spray drying is advantageous for easily achieving a uniform compositional distribution of the sputtering target, since, for example, a difficult crushing operation due to a poor crushability caused by addition of a binder can be omitted, and a powder material formed of spherical particles can be used, providing high flowability.

The raw material powders include at least an oxide, a hydroxide, or a carbonate salt of indium, magnesium, and tin. In addition, the raw material powders may further include a powder of at least one species selected from the oxides of the group A element and the group B element. In mixing of the raw material powders, a dispersant or the like may be added.

The raw material powders may be pulverized/mixed by means of a ball mill. Other than a ball mill, another medium agitation mill such as a bead mill or a rod mill may be employed. Balls and beads serving as an agitation medium may be surface-coated with a resin coating material or the like. As a result, contamination of the powder can be effectively prevented.

The thus-mixed powder material is calcined at 1,000° C. to 1,500° C. When the firing temperature is lower than 1,000° C., calcination is insufficient, thereby failing to form a composite oxide. In this case, MgO remains. When the firing temperature is higher than 1,500° C., sintering proceeds during calcination, and large primary particles are produced. In this case, the sintering density cannot further increase in subsequent firing for sintering.

The calcined powder is wet-pulverized again by means of a ball mill or the like, with a dispersant, a binder, or the like. The obtained powder is granulated through spray drying.

The mean particle size of the granulated powder is adjusted to be 500 μm or less. When the mean particle size of the granulated powder is in excess of 500 μm, cracking and breakage of the compact frequently occur, and particle-like spots emerge on the fired body. If such a fired body is employed as a sputtering target, anomalous discharge and particle generation may occur.

The granulated powder more preferably has a mean particle size of 20 μm to 100 μm. When the particle size falls within the range, the change in volume (i.e., compressibility) before and after cold isostatic press (CIP) molding is small, and generation of cracks of the compact is suppressed, whereby long-size compacts can be consistently produced. When the mean particle size is smaller than 20 μm, the powder tends to be blown up, leading to difficulty in handling.

As used herein, the term “mean particle size” refers to a 50% cumulative value of the particle size distribution determined by means of a sieve-type particle size distribution meter. A specific value of the mean particle size measured by means of “Robot Sifter RPS-105M” (product of Seishin Enterprise Co., Ltd.) is employed.

The granulated powder is molded at a pressure of 100 MPa or higher. Through this molding, a sintered body having a relative density of 97% or higher can be yielded. When the molding pressure is lower than 100 MPa, the formed compact tends to be broken; difficulty is encountered in handling; and the relative density of the sintered body decreases.

CIP is employed as the molding method. The mode of performing CIP may be a typical vertical load type (orthogonal mode), preferably a horizontal load type (lateral mode). If a long planar compact is produced in orthogonal-mode CIP, an unfixed portion of powder in the mold results in variation in thickness, and cracking occurs by self-weight in handling.

The compact is fired at 1,100° C. to 1, 650° C., to thereby yield a sintered body.

When the firing temperature is lower than 1, 100° C., the conductivity and relative density of the product are low, which makes the product to be fitted as a target. When the firing temperature is higher than 1, 650° C., a part of the components evaporates. In this case, the composition of the fired body may vary, and coarse crystal grains may be provided to reduce the mechanical strength of the fired body.

The compact is fired in air or an oxidizing atmosphere, whereby an oxide sintered body of interest can be consistently produced.

The granulated powder is produced from a powder formed of primary particles having a mean particle size of 0.3 μm to 1.5 μm. By use of the raw material powder, the time of mixing/pulverization can be shortened, and dispersibility of the raw material powder in the granulated powder can be enhanced.

The angle of repose of the granulated powder is preferably 32° or less. In this case, flowability of the granulated powder increases, whereby moldability and sinterability are enhanced.

### (Process Step)

The thus-fabricated sintered body is mechanically processed into a plate-form body having a shape, dimensions, and thickness of interest, to thereby yield a sputtering target formed of an In—Mg—Sn—O sintered body. The thus-obtained sputtering target is brazed onto a backing plate.

In this embodiment, a long-size sputtering target having a length greater than 1,000 mm to a longitudinal direction can be fabricated. Thus, a large-scale monolithic sputtering target can be provided. Since possible sputtering of a bonding material (a braze), which would otherwise be present in a joint (i.e., gap between target parts), is prevented, deterioration of the formed film can be prevented, whereby consistent film formation can be achieved. In addition, generation of particles, which would otherwise be caused by re-deposition of sputtered particles deposited in the aforementioned gap, can be suppressed.

### [Assessment of Sputtering Target]

### (Specific Resistivity Distribution)

Specific resistivity is determined through a DC 4-probe method by means of Model sigma-5+ (product of NPS).

After processing of a sintered body, specific resistivity is measured at 5 points of the surface on the sputtering side. The measurements are averaged.

### (Relative Density)

The density of a sintered body is determined through the Archimedes' method by use of mercury, or through direct calculation of dimensions and weight.

### (Crystal Structure)

Formation of a composite oxide in the powder after calcination is confirmed through XRD.

In one example, the apparatuses and measurement conditions employed in the X-ray diffractometry are as follows.

X-ray diffractometer: RINT (product of Rigaku Corporation)
Scanning method: 2θ/θ method
Target: Cu
Tube voltage: 40 kV
Tube current: 20 mA
Scanning speed: 2,000°/min
Sampling width: 0.050°
Divergence slit: 1°
Scattering slit: 1°
Receive slit: 0.3 mm

### [Thin Film Transistor]

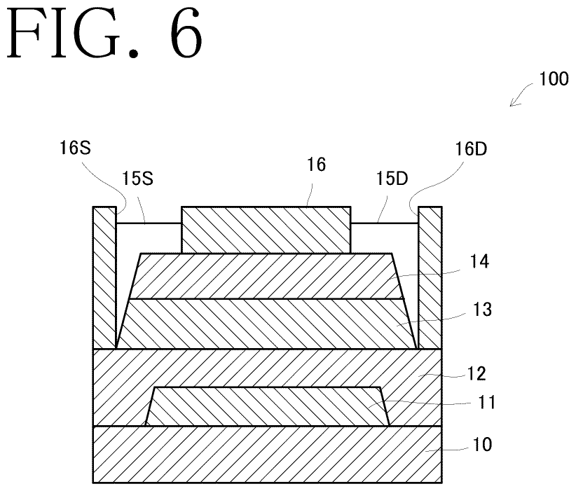

FIG. 6 shows a schematic configuration of the thin film transistor of the present invention.

A thin film transistor 100 of the present embodiment has, on a substrate 10, a gate electrode 11, a gate insulating film 12, an active layer 13, a cap layer 14, a source electrode 15S, a drain electrode 15D, and a protective film 16.

The gate electrode 11 is formed of a conductive film disposed on a surface of the substrate 10. The substrate 10 is typically a transparent glass substrate. The gate electrode 11 is typically a metal single-layer film or a metal multi-layer film, the metal being molybdenum (Mo), titanium (Ti), aluminum (Al), copper (Cu), or the like, and is formed through, for example, sputtering. In the present embodiment, the gate electrode 11 is formed of molybdenum. No particular limitation is imposed on the thickness of the gate electrode 11, and the thickness is, for example, 200 nm. The gate electrode 11 is formed through a film formation technique such as sputtering or vacuum vapor deposition.

The active layer 13 serves as a channel layer of the thin film transistor 100. The thickness of the active layer 13 is, for example, 10 nm to 200 nm. The active layer 13 has a high electron mobility and is formed of an IGZO (In—Ga—Zn—O)-type oxide semiconductor thin film. The active layer 13 is formed through a film formation technique such as sputtering.

The gate insulating film 12 is provided between the gate electrode 11 and the active layer 13. The gate insulating film 12 is formed of, for example, silicon oxide film (SiOx), silicon nitride film (SiNx), or a laminated film thereof. No particular limitation is imposed on the film formation method, and CVD, sputtering, vapor deposition, or the like may be employed. No particular limitation is imposed on the film thickness of the gate insulating film 12, and the thickness is, for example, 200 nm to 400 nm.

The cap layer 14 is formed of the aforementioned oxide semiconductor thin film according to the present invention, and the specific composition of the film is as described above.

The cap layer 14 and the active layer 13 are simultaneously patterned. Any of the aforementioned etchants may be used.

The source electrode 15S and drain electrode 15D are formed on the active layer 13 and the cap layer 14, respectively, such that the two electrodes are separate from each other. The source electrode 15S and the drain electrode 15D each may be formed of, for example, a metal single-layer film or a metal multi-layer film, the metal being aluminum, molybdenum, copper, titanium. As mentioned below, the source electrode 15S and the drain electrode 15D may be simultaneously formed by patterning a metal film. The thickness of the metal film is, for example, 100 nm to 200 nm. The source electrode 15S and the drain electrode 15D are formed through, for example, sputtering, vacuum vapor deposition, or a similar technique.

The source electrode 15S and the drain electrode 15D are coated with the protective film 16. The protective film 16 is formed of, for example, an electrically insulating material such as silicon oxide film (SiOx), silicon nitride film (SiNx), or a laminated film thereof. The protective film 16 is provided so as to shield an element part including the active layer 13 and the cap layer 14 from outside air. No particular limitation is imposed on the film thickness of the protective film 16, and the thickness is, for example, 100 nm to 300 nm. The protective film 16 is formed through a film-formation method, for example, CVD.

After formation of the protective film 16, annealing is conducted, to thereby activate the active layer 13. No particular limitation is imposed on the annealing conditions. In the present embodiment, annealing is carried out in air at about 30° C. for 1 hour. In annealing, the cap layer 14 is conceived to suppress diffusion of hydrogen via heat transfer from the protective layer 16 to the active layer 13.

In the protective film 16, interlayer connection holes 16S, 16D are provided at appropriate positions for connecting the source/drain electrodes 15S, 15D to a wiring layer (not illustrated). The wiring layer is adapted to connect the thin film transistor 100 to a surrounding circuit (not illustrated) and formed of a transparent conductive film such as ITO.

### (Method of Producing Thin Film Transistor)

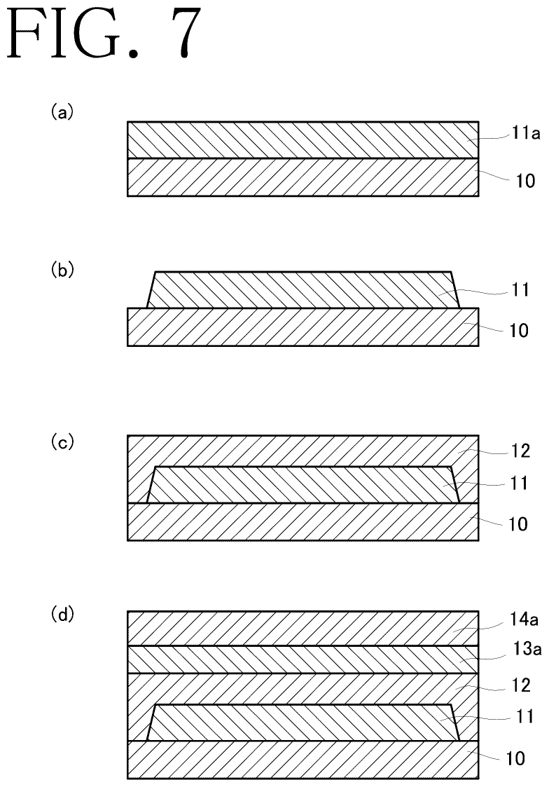

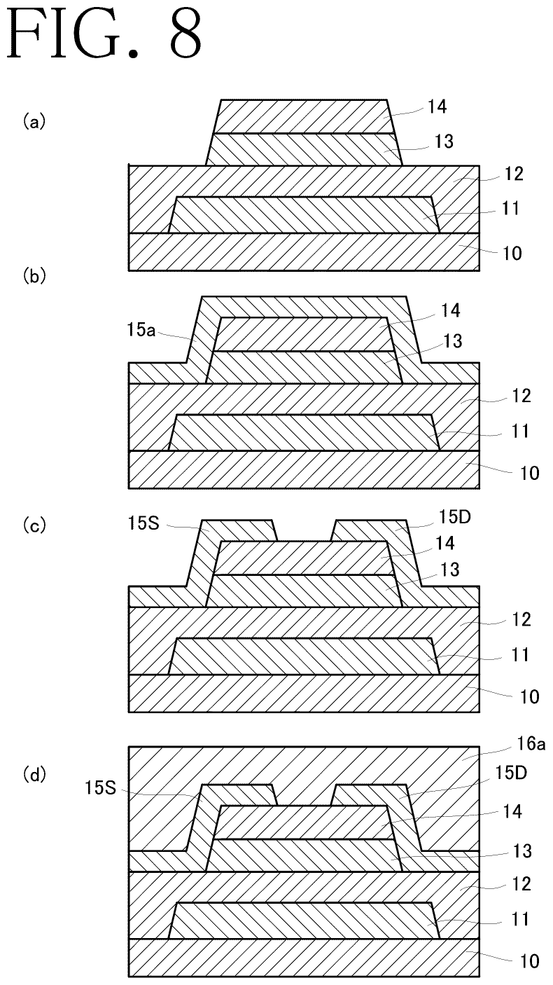

With reference to FIGS. 7 and 8, an embodiment of the method of producing the thin film transistor of the present invention will be described.

As shown in FIG. 7(a), a gate electrode material layer 11a is formed on a substrate 10 through sputtering at room temperature. Then, as shown in FIG. 7(b), a gate electrode 11 is formed through wet etching. Subsequently, as shown in FIG. 7(c), a gate insulating film 12 is formed through CVD. In the embodiment, an SiOx/SiNx stacked body is provided. Then, as shown in FIG. 7(d), an active layer material layer 13a and a cap layer material layer 14a are sequentially formed through sputtering while the substrate 10 is maintained at 100° C. Further, as shown in FIG. 8(a), the active layer material layer 13a and the cap layer material layer 14a is patterned through etching, to thereby form an active layer 13 and a cap layer 14. Etching is conducted by use of an etchant, for example, a sulfuric acid-nitric acid-based etchant. Thereafter, in one annealing procedure, the stacked body is annealed in air at 400° C. for 1 hour. Subsequently, as shown in FIG. 8(b), a source/drain metallic material layer 15a is formed through sputtering at room temperature, and as shown in FIG. 8(c), a source electrode 15S and a drain electrode 15D are formed through patterning. Finally, as shown in FIG. 8(d), a protective film material layer 16a is formed through CVD. The protective film material layer 16a is, for example, an SiOx film having a thickness of 300 nm. The protective film material layer 16a is annealed in air at 300° C. and then patterned through dry etching, to thereby form interlayer connection holes 16S, 16D with respect to the source electrode 15S and the drain electrode 15D (see FIG. 6).

In the thin film transistor (TFT) according to the present invention as described above, no shifting of Vth occurs during stacking of the cap layer 14 on the high-electron mobility active layer 13 formed of a material exhibiting a small band gap Eg. Thus, external undesired factors in fabrication of TFTs can be successfully suppressed.

More specifically, the cap layer 14 of the present invention can suppress damage to the active layer 13 during a hydrogen process in fabrication of TFTs and patterning of the source electrode 15S and the drain electrode 15D.

Meanwhile, if the suppression effect of the cap layer 14 is not present, diffusion of hydrogen into the active layer 13 in the hydrogen process results in a drop in electrical resistance, thereby failing to attain favorable TFT characteristics, which is problematic. Also, when the effect of the cap layer 14 on suppression of etching damage to the active layer 13 is not attained, a weak bond in the oxide semiconductor film of the active layer 13 is broken by the etchant, to thereby undesirably provide defects in the film. In this case, the S value, one of the TFT characteristics, deteriorates, failing to attain favorable transistor characteristics, which is problematic.

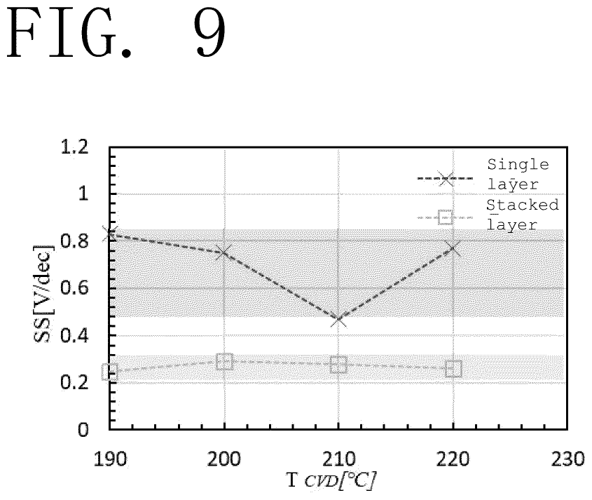

FIG. 9 is a graph variation in S value in a thin film transistor, while the temperature of the substrate of a protective layer 16 is varied during film formation by CVD, in comparison of the configuration of FIG. 6 (with the cap layer 14 formed of the oxide semiconductor thin film of the present invention) (i.e., stacked layer) with a similar configuration having no cap layer 14 (i.e., single layer) (not illustrated). As the active layer 13, In—Sn—Ge—O+α is used, and the cap layer 14 is formed of In—Mg—Sn—O of the present invention. Each layer has a thickness of 15 nm.

As is clear from FIG. 9, in the case of a single layer structure having no cap layer 14, the S value (a TFT characteristic) increases resulting in undesired deterioration, when the active layer 13 has received etching damage. In contrast, in the case of a stacked layer structure including the cap layer 14 of the present invention, etching damage is suppressed, whereby an increase in S value is suppressed.

### EXAMPLES

### Examples 1 to 9

Indium oxide, magnesium hydroxide, and tin oxide were weighed so that the compositions shown in Table 3 below were attained, and mixed by means of a ball mill. The thus-obtained particle powder was calcined and then fired in an oxygen atmosphere, to thereby yield a sintered body.

Table 3 shows measurements of relative density and specific resistivity of sintered bodies.

In Examples 1 to 9, when raw materials; i.e., indium oxide, magnesium hydroxide, and tin oxide were calcined at a 1,000° C. to 1,500° C. and fired in an oxygen atmosphere, sintered body each having a relative density of 90% or higher were yielded. Also, when the raw materials we re calcined at a 1,000° C. to 1,200° C. and fired in an oxygen atmosphere at 1,500° C. or higher, sintered body each having a relative density of 97% or higher and specific resistivity of 10 mΩ·cm or less were yielded.

In any of Examples 1 to 9, no MgO was found to remain after calcination.

### Comparative Examples 1 to 5

In Comparative Example 1, the procedure of Example 1 was repeated, except that the calcination temperature was adjusted to 950° C., lower than 1,000° C. As a result, MgO was found to remain after calcination.

In Comparative Example 2, the procedure of Example 3 was repeated, except that sintering was caused to occur in air. As a result, the relative density was lower than 90%.

In Comparative Example 3, the procedure of Example 3 was repeated, except that the firing temperature to cause sintering was adjusted to 1,650° C. As a result, coarse crystal grains were formed, which is not preferred to provide a sputtering target.

In Comparative Example 4, the procedure of Example 3 was repeated, except that MgO was used as an Mg source. As a result, the relative density was lower than 90%.

In Comparative Example 5, the procedure of Example 3 was repeated, except that MgCO₃ was used as an Mg source. As a result, the relative density was lower than 90%.

TABLE 3

| | | | | | | | | Calcining | | Sintering | | | | Specific |
|---|---|---|---|---|---|---|---|---|---|---|---|---|---|---|
| | Composition | | | | Raw materials | | | temp. | | temp. | Time | | Relative | resistivity |
| Exs. | Target | In | Mg | Sn | In | Mg | Sn | (° C.) | MgO | (° C.) | (hr) | Atm. | density | (mΩ · cm) |
| 1 | InMgSn-1 | 44 | 42 | 14 | In₂O₃ | Mg(OH)₂ | SnO₂ | 1,000 | No | 1,500 | 5 | O₂ | 97.2% | 8 |
| 2 | InMgSn-1 | 44 | 42 | 14 | In₂O₃ | Mg(OH)₂ | SnO₂ | 1,100 | No | 1,550 | 5 | O₂ | 98.5% | 3 |
| 3 | InMgSn-1 | 44 | 42 | 14 | In₂O₃ | Mg(OH)₂ | SnO₂ | 1,200 | No | 1,550 | 5 | O₂ | 99.4% | 2 |
| 4 | InMgSn-1 | 44 | 42 | 14 | In₂O₃ | Mg(OH)₂ | SnO₂ | 1,300 | No | 1,550 | 5 | O₂ | 96.5% | 2 |
| 5 | InMgSn-1 | 44 | 42 | 14 | In₂O₃ | Mg(OH)₂ | SnO₂ | 1,400 | No | 1,550 | 5 | O₂ | 95.3% | 3 |
| 6 | InMgSn-1 | 44 | 42 | 14 | In₂O₃ | Mg(OH)₂ | SnO₂ | 1,500 | No | 1,550 | 5 | O₂ | 91.2% | 3 |
| 7 | InMgSn-2 | 50 | 30 | 20 | In₂O₃ | Mg(OH)₂ | SnO₂ | 1,200 | No | 1,550 | 5 | O₂ | 98.4% | 2 |
| 8 | InMgSn-3 | 54 | 31 | 15 | In₂O₃ | Mg(OH)₂ | SnO₂ | 1,200 | No | 1,550 | 5 | O₂ | 98.0% | 2 |
| 9 | InMgSn-4 | 58 | 25 | 17 | In₂O₃ | Mg(OH)₂ | SnO₂ | 1,200 | No | 1,550 | 5 | O₂ | 97.4% | 2 |

TABLE 4

| | | | | | | | | Calcining | | Sintering | | | | Specific |
|---|---|---|---|---|---|---|---|---|---|---|---|---|---|---|
| Comp. | Composition | | | | Raw materials | | | temp. | | temp. | Time | | Relative | resistivity |
| Exs. | Target | In | Mg | Sn | In | Mg | Sn | (° C.) | MgO | (° C.) | (hr) | Atm. | density | (mΩ · cm) |
| 1 | InMgSn-1 | 44 | 42 | 14 | In₂O₃ | Mg(OH)₂ | SnO₂ | 950 | Yes | — | — | — | — | — |
| 2 | InMgSn-1 | 44 | 42 | 14 | In₂O₃ | Mg(OH)₂ | SnO₂ | 1,200 | No | 1,550 | 5 | Air | 89.5% | 15 |
| 3 | InMgSn-1 | 44 | 42 | 14 | In₂O₃ | Mg(OH)₂ | SnO₂ | 1,200 | No | 1,650 | 5 | O₂ | 96.5% | 2* |
| 4 | InMgSn-1 | 44 | 42 | 14 | In₂O₃ | MgO | SnO₂ | 1,200 | No | 1,550 | 5 | O₂ | 88.8% | 13 |
| 5 | InMgSn-1 | 44 | 42 | 14 | In₂O₃ | MgCO₃ | SnO₂ | 1,200 | No | 1,550 | 5 | O₂ | 86.8% | 25 |

Note:
*Coarse crystal grains

### Thin Film Transistor Production Example 1

As shown in the configuration of FIG. 6, a thin film transistor having the cap layer 14 formed of the oxide semiconductor thin film of the present invention was fabricated.

The active layer 13 was formed from In—Sn—Ge—O+α as exemplified in Table 1, and the film thickness was adjusted to 50 nm. The cap layer 14 was formed from In—Mg—Sn—O (composition: In 54, Mg 31, and Sn 15) of the present invention, and the film thickness was adjusted to 50 nm.

### Thin Film Transistor Comparative Production Example 1

The same procedure was repeated, except that the cap layer 14 as shown in FIG. 6 was not provided, to thereby fabricate a thin film transistor.

### Thin Film Transistor Comparative Production Example 2

The same procedure was repeated, except that a cap layer formed of a conventional IGZO type having a composition modified from IGZO was used in the thin film transistor shown in FIG. 6, to thereby fabricate a thin film transistor.

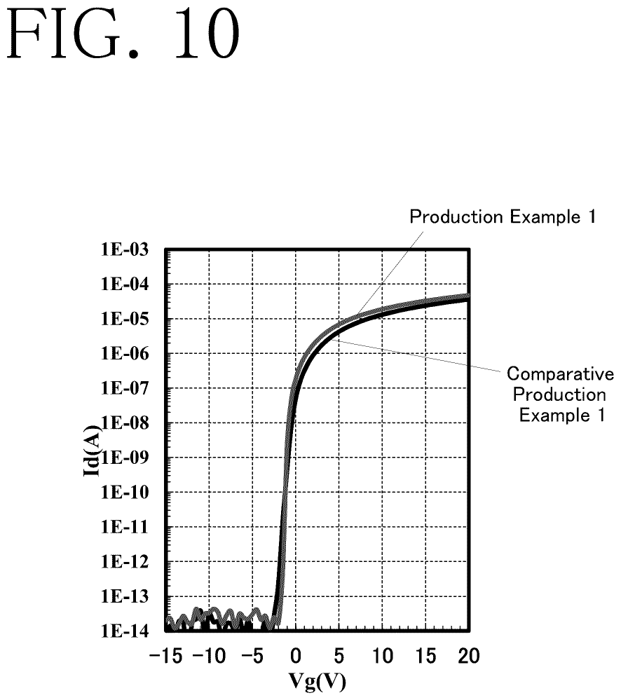

FIG. 10 is a graph showing comparison in Vth, between the case of a thin film transistor having the cap layer 14 formed of the oxide semiconductor thin film of the present invention (i.e., stacked layer, Production Example 1) and the case of a thin film transistor having no cap layer 14 (i.e., single layer, Comparative Production Example 1).

As is clear from FIG. 10, in the case of a stacked structure provided with the cap layer 14 of the present invention (Production Example 1), the threshold voltage Vth was almost equivalent to that of the case of a structure not provided with the cap layer 14 (single layer, Comparative Production Example 1). Thus, shifting of Vth attributable to provision of the cap layer 14 was not observed.

Additionally, the band gap (Eg) of the single-layer structure in Comparative Production Example 1 was 2.7 eV, whereas the Eg of the cap layer 14 in the stacked structure was 3.1 eV. The difference was only 0.4 eV, which is relatively small.

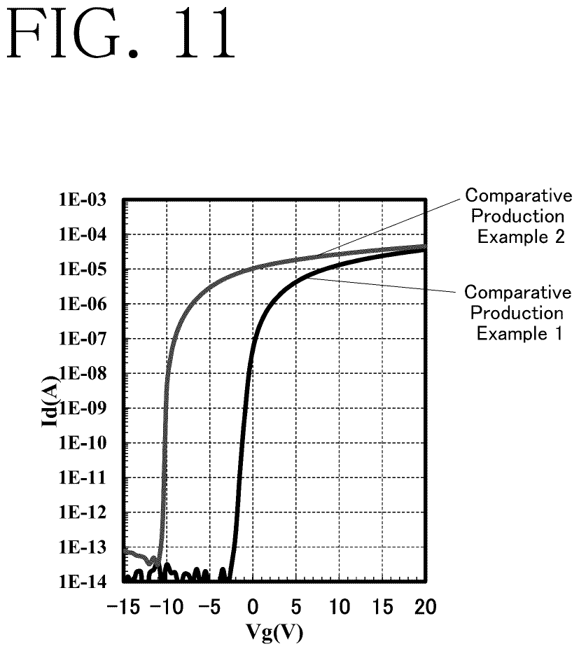

FIG. 11 shows the comparison in threshold voltage (Vth) between a thin film transistor of Comparative Production Example 2, which has the same device structure as in FIG. 6 but uses a cap layer with IGZO type having a composition modified from IGZO, and a thin film transistor of Comparative Production Example 1 without a cap layer.

As shown in FIG. 11, the threshold voltage (Vth) of the thin film transistor in Comparative Production Example 2 (stacked structure) exhibited a significant shift compared to the thin film transistor in Comparative Production Example 1 (single-layer structure).

Furthermore, the band gap (Eg) of the active layer in the single-layer structure of Comparative Production Example 1 was 2.7 eV, whereas the band gap (Eg) of the cap layer in the stacked structure of Comparative Production Example 2 was 3.4 eV.

This indicates a substantial difference in band gap (Eg) compared to the band gap difference between the cap layer 14 formed of the oxide semiconductor thin film of the present invention and the single-layer structure's active layer.

1-21. (canceled)

22. An oxide semiconductor thin film stacked body which comprises:
an active layer exhibiting a band gap of 3 eV or less, and
a cap layer which is stacked on the active layer;
wherein the cap layer is formed of an oxide semiconductor containing an oxide of indium, magnesium, and tin represented by formula In_{X}Mg_{Y}Sn_{Z} as a main component, and X is 0.32 to 0.65, Y is 0.17 to 0.46, Z is greater than 0 and 0.22 or smaller, satisfying X+Y+Z=1;
wherein the cap layer exhibits a band gap of 2.5 eV to 3.4 eV.

23. The oxide semiconductor thin film stacked body according to claim 22, wherein the cap layer has an etching rate suited for patterning together with the active layer.

24. The oxide semiconductor thin film stacked body according to claim 23, wherein the etching rate of the cap layer in etching with a sulfuric acid-nitric acid-based etchant or an acetic acid-based etchant is 1 nm/sec or more.

25. The oxide semiconductor thin film stacked body according to claim 22, the cap layer exhibits a resistivity of 1E+2Ω/square or higher after hydrogen annealing.

26. The oxide semiconductor thin film stacked body according to claim 22, wherein the oxide semiconductor forming the cap layer further contains a group A element, which is defined as at least one element selected from among Si, Ti, W, Zr, Nb, Ni, Ge, Ta, Al, or Y.

27. The oxide semiconductor thin film stacked body according to claim 26, wherein the oxide semiconductor forming the cap layer contains Si in an amount of 4 at % or less, Ti in an amount of 6 at % or less, W in an amount of 6 at % or less, Zr in an amount of 7 at % or less, Nb in an amount of 7 at % or less, Ni in an amount of 7 at % or less, Ge in an amount of 7 at % or less, Ta in an amount of 8 at % or less, Al in an amount of 8 at % or less, and Y in an amount of 9 at % or less, and has a group A element content less than 10 at %.

28. The oxide semiconductor thin film stacked body according to claim 22, wherein the oxide semiconductor forming the cap layer further contains further contains a group B element, which is defined as at least one element selected from among Mo, Sb, Hf, La, Fe, Ga, Zn, Ca, or Sr.

29. The oxide semiconductor thin film stacked body according to claim 28, wherein the oxide semiconductor forming the cap layer contains Mo in an amount of 10 at % or less, Sb in an amount of 13 at % or less, Hf in an amount of 13 at % or less, La in an amount of 13 at % or less, Fe in an amount of 21 at % or less, Ga in an amount of 27 at % or less, Zn in an amount of 38 at % or less, Ca in an amount of 38 at % or less, and Sr in an amount of 38 at % or less, wherein a total amount of the elements other than In, Mg, and Sn is 38 at % or less.

30. A method for producing an oxide semiconductor thin film stacked body, the method comprising:
forming an active layer exhibiting a band gap of 3 eV or less, and
forming a cap layer on the active layer, to thereby form an oxide semiconductor thin film stacked body;
wherein the cap layer is formed of an oxide semiconductor containing an oxide of indium, magnesium, and tin represented by formula In_{X}Mg_{Y}Sn_{Z} as a main component, and X is 0.32 to 0.65, Y is 0.17 to 0.46, Z is greater than 0 and 0.22 or smaller, satisfying X+Y+Z=1;
wherein the cap layer exhibits a band gap of 2.5 eV to 3.4 eV.

31. The method for producing an oxide semiconductor thin film stacked body according to claim 30, wherein the cap layer is produced through sputtering a sputtering target which is formed of an oxide sintered body of an oxide of indium, magnesium, and tin represented by formula In_{X}Mg_{Y}Sn_{Z}, and
wherein X is 0.32 to 0.65, Y is 0.17 to 0.46, Z is greater than 0 and 0.22 or smaller, satisfying X+Y+Z=1.

32. The method for producing an oxide semiconductor thin film stacked body according to claim 30, wherein the cap layer has an etching rate suited for patterning together with the active layer.

33. The method for producing an oxide semiconductor thin film stacked body according to claim 32, wherein the etching rate of the cap layer in etching with a sulfuric acid-nitric acid-based etchant or an acetic acid-based etchant is 1 nm/sec or more.

34. The method for producing an oxide semiconductor thin film stacked body according to claim 30,
the cap layer exhibits a resistivity of 1E+2Ω/square (cm²) or higher after hydrogen annealing.

35. The method for producing an oxide semiconductor thin film stacked body according to claim 30,
the oxide semiconductor forming the cap layer further contains a group A element, which is defined as at least one element selected from among Si, Ti, W, Zr, Nb, Ni, Ge, Ta, Al, or Y.

36. The method for producing an oxide semiconductor thin film stacked body according to claim 35, wherein the oxide semiconductor forming the cap layer contains Si in an amount of 4 at % or less, Ti in an amount of 6 at % or less, W in an amount of 6 at % or less, Zr in an amount of 7 at % or less, Nb in an amount of 7 at % or less, Ni in an amount of 7 at % or less, Ge in an amount of 7 at % or less, Ta in an amount of 8 at % or less, Al in an amount of 8 at % or less, and Y in an amount of 9 at % or less, and has a group A element content less than 10 at %.

37. The method for producing an oxide semiconductor thin film stacked body according to claim 30, wherein the oxide semiconductor forming the cap layer further contains further contains a group B element, which is defined as at least one element selected from among Mo, Sb, Hf, La, Fe, Ga, Zn, Ca, and Sr.

38. The method for producing an oxide semiconductor thin film stacked body according to claim 37, wherein the oxide semiconductor forming the cap layer contains Mo in an amount of 10 at % or less, Sb in an amount of 13 at % or less, Hf in an amount of 13 at % or less, La in an amount of 13 at % or less, Fe in an amount of 21 at % or less, Ga in an amount of 27 at % or less, Zn in an amount of 38 at % or less, Ca in an amount of 38 at % or less, and Sr in an amount of 38 at % or less, wherein a total amount of the elements other than In, Mg, and Sn is 38 at % or less.

39. The method for producing an oxide semiconductor thin film stacked body according to claim 30, wherein the method further comprises etching the cap layer together with the active layer.

40. A thin film semiconductor device, which comprises an active layer and a cap layer as recited in claim 22.

41. A method for producing a thin film semiconductor device as recited in claim 30, the method comprising:
forming a gate insulating film on a gate electrode;
forming an active layer through sputtering;
forming the cap layer on the active layer through sputtering;
patterning a stacked film of the active layer and the cap layer through wet etching;
forming a metal layer disposed on the active layer and the cap layer which have been patterned and serve as an underlayer film; and
patterning the metal layer through wet etching, to thereby form a source electrode and a drain electrode.
